(19) United States
(12) Patent Application Publication
(10) Pub. No.: US 2026/0243804 A1
(43) Pub. Date: Aug. 20, 2026

(54) Device for measuring the main currents of an electrical installation, measuring method and protection method using such a device

(71) Applicant: Schneider Electric Industries SAS, Rueil Malmaison (FR)

(72) Inventors: Bruno Bordet, Rueil Malmaison (FR); Loïc Rondot, Rueil Malmaison (FR)

(21) Appl. No.: 19/241,095

(22) Filed: Jun. 17, 2025

(30) Foreign Application Priority Data
Jun. 24, 2024 (FR) FR2406779

(51) Int. Cl. G01R 15/18; G01R 19/10

(52) U.S. Cl. CPC G01R 15/18; G01R 19/10

(57) ABSTRACT

The invention relates to a device (1) for measuring the main currents of an electrical installation comprising N conductors (3). The device comprises a closed magnetic circuit (5), at least N−1 main current measuring windings (11), a holding structure (6), means (13) for measuring a voltage (V11) at the terminals of the main current measuring windings (11) and a computing unit (15). Each main current measuring winding comprises two windings in series (111, 112) which are each wound around a part of the magnetic circuit (5), are not equidistant from at least one of the conductors (3), and have an opposite winding direction from one winding (111, 112) to the other, so that a uniform magnetic field in the magnetic circuit (5) generates a voltage which cancels out at the terminals of the main current measuring winding (11).

### CROSS-REFERENCE TO RELATED APPLICATION

This application claims the benefit of French Patent Application No. 2406779, filed Jun. 24, 2024, the entire disclosure of which is incorporated herein by reference.

### BACKGROUND

The present invention relates to a device for measuring the main currents of an electrical installation. It also relates to a method for measuring the main currents of an electrical installation using such a device. It also relates to a method for protecting an electrical installation using such a device.

It is useful to know the currents flowing in each of the phase or neutral wires of an electrical installation, referred to as main currents, for the purposes of indication or of protection. For this purpose, the use of sensors with various technologies is known, such as CT sensors, resistive shunts, Rogowski sensors or Hall-effect sensors.

However, the measurement of the main currents by these means requires the installation of several sensors, generally one per conductor. In addition, these sensors are generally added to a sensor for measuring the differential current. This multiplicity of sensors in the installation leads to a significant space requirement and cost.

### SUMMARY

The aim of the invention is accordingly to provide a device for measuring the main currents of an electrical installation allowing the total number of sensors in the installation to be reduced, in order to obtain a gain of space, a gain on the cost of the sensors and on the cost of the assemblies.

For this purpose, the subject of the invention is a device for measuring the main currents of an electrical installation comprising a number N of conductors through which a main current \vec{I} is flowing, comprising:
a closed magnetic circuit, composed of a ferromagnetic material and set up to surround the conductors;
at least N−1 main current measuring windings, each main current measuring winding comprising two windings in series which:
   i. are each wound around a part of the closed magnetic circuit,
   ii. are not equidistant from at least one of the conductors, so that the main current \vec{I} flowing in said at least one conductor generates a different magnetic flux within each of the two windings, and
   iii. have an opposite winding direction from one winding to the other, so that a uniform magnetic field in the magnetic circuit generates a voltage which cancels out at the terminals of the main current measuring winding;
a holding structure set up to hold the conductors in a given disposition where the conductors are non-coaxial;
means for measuring a voltage at the terminals of the N−1 main current measuring windings; and
a computing unit, connected to the means for measuring the voltage.

By virtue of the invention, only one sensor is needed to carry out the measurement of the currents flowing in several conductors simultaneously. Indeed, since the conductors are non-coaxial, the currents flowing in various conductors will have different influences on a resulting magnetic field at a given point of the magnetic circuit. Thus, since the main current measuring windings are located around a part of the magnetic circuit, the voltage generated at the terminals of a main current measuring winding is dependent on the main currents. Thus, by measuring the voltages at the terminals of the primary current windings, and by virtue of the knowledge of the geometry or of a calibration operation, it is possible to obtain as many equations on the main currents as there are measurement windings of the primary current. Disposing of the at least N−1 equations thus obtained, potentially completed by an additional equation resulting from the vector equality of the main currents of an installation, it is possible to deduce the value of each main current, using the single device for measuring the main currents. This device obviates the need for the multiplicity of usual sensors for measuring the main current, and hence allows a gain of space and of costs by reducing the total number of sensors in the installation.

According to other advantageous aspects of the invention, the device for measuring the main currents comprises one or more of the following features, taken in isolation or according to all the technically possible combinations:
the magnetic circuit has a symmetrical shape, in other words it comprises at least one axis of symmetry and/or a center of symmetry;
the at least one axis of symmetry is also an axis of symmetry of the holding structure;
the two windings of each main current measuring winding are disposed symmetrically to one another with respect to the center of symmetry of the magnetic circuit or with respect to the at least one axis of symmetry;
there are 2 main conductors, one of the conductors being a phase wire and the other being a neutral wire of a single-phase electrical installation or another phase wire of a split-phase electrical installation;
there are 3 conductors, two of the three conductors being phase wires and the third conductor being a third phase wire or a neutral wire of an electrical installation;
there are 4 conductors, three of the conductors being phase wires and the fourth being a neutral wire of an electrical installation;
the device comprises a differential current measuring winding, wound in a regular manner around the closed magnetic circuit, and a means for measuring a current flowing in the differential current measuring winding, connected to the computing unit or to another computing unit.

The invention also relates to a method for measuring the main currents of an electrical installation, implemented by the computing unit of a device for measuring the main currents conforming to what precedes and comprising steps consisting in:
receiving values of the voltage at the terminals of each main current measuring winding, measured by the voltage measurement means;
converting the values of the voltage at the terminals of each main current measuring winding into values of the main currents, corresponding to the currents flowing in the main conductors; then
rendering the values of the main currents in analog or digital form.

The invention also relates to a method for protecting an electrical installation, the electrical installation having a leakage current defined as a difference between the sum of the main currents entering the electrical installation and the sum of the main currents exiting the electrical installation, the method being implemented by the computing unit of a main current measuring device according to the invention, comprising steps consisting in:
receiving a value of the current flowing in the differential current measuring winding, measured by the current measuring means;
deducing from this, by virtue of a coefficient of proportionality obtained by prior calibration, the value of the leakage current; then
controlling a switch allowing a power supply of the electrical installation to be interrupted if and only if the value of the leakage current is higher than a predetermined threshold value.

### BRIEF DESCRIPTION OF THE DRAWINGS

The invention will become more clearly apparent upon reading the description that follows, given solely by way of non-limiting example, and presented with reference to the drawings in which:

FIG. 1 is an overall diagram of a device for measuring the main currents according to the invention, in the case of an installation with two conductors according to a first embodiment of the invention,

FIG. 2 is a diagram of a part of a device for measuring the main currents according to the invention, in the case of an installation with two conductors according to a second embodiment of the invention,

FIG. 3 is a diagram of a part of a device for measuring the main currents according to the invention, in the case of an installation with three conductors,

FIG. 4 is a diagram of a part of a device for measuring the main currents according to the invention, in the case of a four-pole installation.

### DETAILED DESCRIPTION

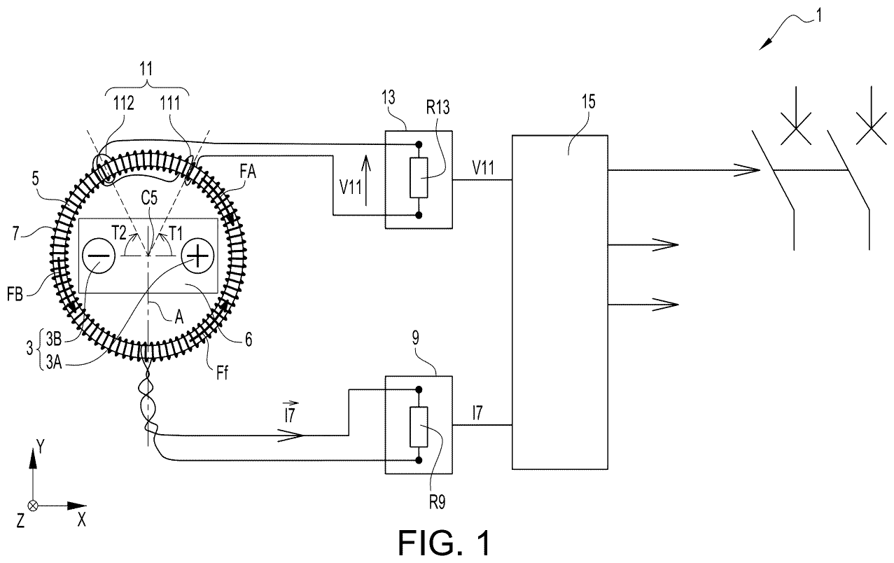

The device for measuring the main currents 1 shown in FIG. 1 is integrated into an input of an electrical installation, where circuit breakers and current measurement sensors are usually disposed. In order to facilitate the understanding, the description is initially limited to a single-phase electrical installation. The installation is then supplied by two conducting wires, called conductors 3, in which main currents \vec{I} flow. The first conductor 3A is a phase wire, via which a first main current \vec{IA} enters into the electrical installation. The second conductor 3B is a neutral wire, via which a second main current \vec{IB} exits from the electrical installation. The conductors 3 supply an assembly of electrical devices belonging to the electrical installation.

In the absence of an anomaly, the main currents \vec{IA} and \vec{IB} are equal in absolute value. In the case of an anomaly in the electrical installation, there exists a leakage current \vec{If} in the electrical installation, also called differential current, such that \vec{IA}=\vec{IB}+\vec{If}. The leakage current \vec{If} is a potential source of danger for users of the electrical installation or for the aforementioned electrical devices. The value of the leakage current \vec{If} is generally low compared to the values of the main currents \vec{IA} and \vec{IB}.

The function of the device for measuring the main currents 1 is to measure the values of the main currents \vec{IA} and \vec{IB} for the purposes of indication or of protection. In particular, the measurement of the main currents \vec{IA} and \vec{IB} is useful for monitoring the electrical power consumption of the installation.

Advantageously, and in the example in FIG. 1, the device for measuring the main currents 1 also has the function of measuring the leakage current \vec{If}. This measurement is useful for protecting the electrical installation by interrupting the power supply in the case of the presence of a leakage current \vec{If}, according to the known principle of a differential circuit breaker.

For this purpose, the device for measuring the main currents 1 comprises a magnetic circuit 5, a holding structure 6, a differential current measuring winding 7, a current measuring means 9, a main current measuring winding 11, a voltage measuring means 13 and a computing unit 15.

The magnetic circuit 5 surrounds the conductors 3. In other words, the conductors 3 pass through the magnetic circuit 5. The magnetic circuit 5 extends in a plane (x,y) shown in FIGS. 1 to 4. This magnetic circuit is closed and composed of a ferromagnetic material, so that a magnetic flux F can run through it. The magnetic circuit 5 is advantageously of symmetrical shape, in other words it comprises at least one axis of symmetry A and/or a center of symmetry C5. The axis of symmetry A is defined as the intersection of the plane (x,y) with a plane of symmetry of the magnetic circuit 5, preferably perpendicular to the plane (x,y). Thus, the axis of symmetry A is perpendicular to the axis z, hence to the conductors 3, and is contained within the plane (x,y), in other words in the plane of the magnetic circuit 5. The magnetic circuit 5 shown in FIG. 1 has a circular shape with a center C5, which allows the compactness and the quantity of material of the device 1 to be optimized.

As a variant not shown of the invention, the magnetic circuit 5 may have an oblong, rectangular or any given shape.

Preferably, the conductors 3 are held by the holding structure 6 in a position where they are perpendicular to the magnetic circuit 5. In other words, the conductors 3 run parallel to an axis z normal to the plane (x,y).

The holding structure 6 is rigidly attached to the magnetic circuit 5 and holds the conductors 3 in a given disposition in which they are non-coaxial. By way of example, the holding structure may be a straddle made of insulating material that the conductors 3 pass through and which is disposed near to the magnetic circuit 5, without necessarily being coplanar with this circuit.

Advantageously, the aforementioned axis of symmetry A is also an axis of symmetry of the holding structure 6. In other words, the assembly composed of the holding structure 6 and of the magnetic circuit 5 defines at least one axis of symmetry A.

The differential current measuring winding 7 is, in a known manner, wound in a regular manner around the magnetic circuit 5. In operation, the main currents \vec{IA} and \vec{IB} flowing in the conductors 3A and 3B generate magnetic fluxes FA and FB in the magnetic circuit 5. Since the main currents \vec{IA} and \vec{IB} are in opposite directions, the magnetic fluxes FA and FB are in opposite directions.

In the absence of an anomaly, since the main currents \vec{IA} and \vec{IB} are of the same value and in opposing directions, the same is true for the magnetic fluxes FA and FB, which therefore cancel each other out in the magnetic circuit 5 and are not detected by the differential current winding 7 since balanced and symmetrical.

In the case of an anomaly, since the main currents \vec{IA} and \vec{IB} no longer have the same value, in the magnetic circuit 5 there exists a differential magnetic flux Ff resulting from the difference between the magnetic fluxes FA and FB, hence from the difference between the main currents \vec{IA} and \vec{IB}, hence from the leakage current \vec{If}. This differential magnetic flux Ff generates a resulting current \vec{I7} in the differential current winding 7. In other words, the resulting current \vec{I7} in the differential current winding 7 is proportional to the leakage current \vec{If} and independent of the main currents \vec{IA} and \vec{IB}. The differential current measuring winding 7 forms a circuit in series with the current measuring means 9. The current measuring means 9 is typically an ammeter and exhibits a very low ammeter internal resistance R9, for example lower than 100Ω. Thus, the differential current measuring winding 7 is virtually in short-circuit, so that the operation as a current transformer of the differential current measuring winding 7 is only very little or not at all impacted by the current measuring means 9.

The current measuring means 9 thus measures the current \vec{I7} flowing in the differential current measuring winding 7. According to the above, the current measuring means 9 therefore measures a current proportional to the leakage current \vec{If} and independent of the main currents \vec{IA} and \vec{IB}.

There are at least N−1 main current measuring windings 11, where N is the number of conductors 3. In the embodiment considered in FIG. 1, where N is equal to 2, the device for measuring the main currents 1 comprises a single main current measuring winding 11.

The main current measuring winding 11 comprises two windings 111 and 112. As can be seen in FIG. 1, the two windings 111 and 112 are connected in series and are each wound around a part of the magnetic circuit 5. The two windings 111 and 112 are not equidistant from one and/or the other of the conductors 3A and 3B, in other words there exists at least one conductor 3A or 3B such that the distance from the first winding 111 to this conductor 3A or 3B is different from the distance from the second winding 112 to this conductor 3A or 3B. Thus, the main current \vec{IA} or \vec{IB} flowing in this conductor 3A or 3B generates a different magnetic flux within each of the two windings 111 and 112. This is possible by virtue of the aforementioned disposition, provided by the holding structure 6, in which disposition the conductors 3 are non-coaxial. In the example in FIG. 1, the two windings 111 and 112 are not equidistant from the conductor 3A nor are they equidistant from the conductor 3B.

Thus, the magnetic fluxes FA and FB generated by the main currents \vec{IA} and \vec{IB} flowing in the conductors 3A and 3B have a different influence on a resulting magnetic flux within a winding 111 or 112. In particular, in the disposition shown in FIG. 1, the first winding 111 is closer to the primary conductor 3A than the second winding 112. As a consequence, the main current \vec{IA} has a greater contribution on the resulting magnetic flux within the first winding 111 than on the resulting magnetic flux within the second winding 112. Similarly, the main current \vec{IB} has a greater contribution on the resulting magnetic flux within the second winding 112 than on the resulting magnetic flux within the first winding 111.

The orientation angle T1 is defined between a straight line passing through the centers of the conductors 3A and 3B and a straight line passing through the center of symmetry C5 of the magnetic circuit 5 and through the position of the first winding 111 on the magnetic circuit 5. Similarly, the orientation angle T2 is defined between the straight line passing through the centers of the conductors 3A and 3B and a straight line passing through the center of symmetry C5 of the magnetic circuit 5 and through the position of the second winding 112.

In the first embodiment shown in FIG. 1, the two windings 111 and 112 of each main current measuring winding 11 are disposed symmetrically to one another with respect to the axis of symmetry A. In other words, the angles T1 and T2 are equal in absolute value and in opposite directions.

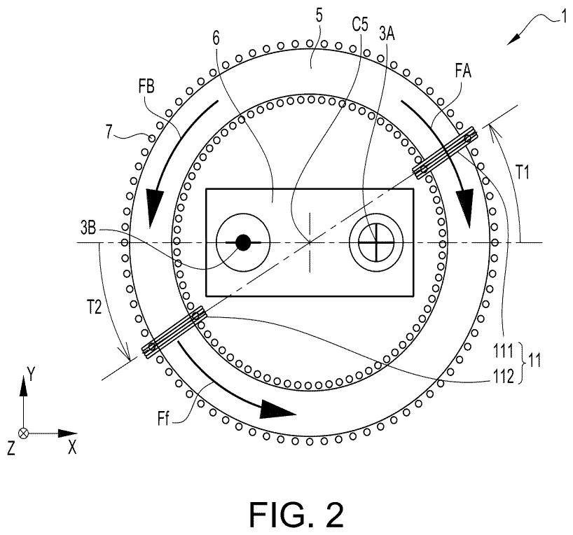

In the second embodiment of the invention shown in FIG. 2, the two windings 111 and 112 of each main current measuring winding 11 are disposed symmetrically to one another with respect to the center C5 of the magnetic circuit 5. In other words, the angles T1 and T2 are equal.

This symmetry is advantageous for the sake of simplicity but is not a strictly indispensable feature of the invention. Indeed, for any given number of conductors 3 and any given geometry of the magnetic circuit 5, a numerical simulation may allow an optimum position of the two windings 111 and 112 of the main current measuring winding 11 to be defined. However, the optimum positioning of the two windings 111 and 112 is facilitated by the presence of the axis of symmetry A and/or of the center of symmetry C5. The two windings 111 and 112 are then positioned optimally while at the same time being themselves symmetrical to one another with respect to the axis of symmetry A or with respect to the center of symmetry C5.

In the two embodiments in FIGS. 1 and 2, the two windings 111 and 112 are furthermore wound in opposite directions. Thus, the differential magnetic flux Ff, uniform in the magnetic circuit 5, generates a resulting voltage of opposite polarity at the terminals of each of the two windings 111 and 112. Since these two windings are in series, these contributions cancel each other out, so that the resulting voltage V11 at the terminals of the main current measuring winding 11 is independent of the differential flux Ff, and hence of the leakage current \vec{If}.

For the same reason, the resulting magnetic flux within the first winding 111, which results mainly from the magnetic flux FA generated by the main current \vec{IA}, and the resulting magnetic flux within the second winding 112, which results mainly from the magnetic flux FB generated by the main current \vec{IB} and in the opposite direction to the magnetic flux FA, generate in the windings 111 and 112 voltages which are added together without compensating one another. Thus, the resulting voltage V11 at the terminals of the main current measuring winding 11 depends on the main currents \vec{IA} and \vec{IB} while being independent of the leakage current \vec{If}.

As explained hereinabove, the presence of the two windings in series 111 and 112 with opposite winding directions allows the measurement of the main currents \vec{IA} and \vec{IB} to be rendered independent of the leakage current \vec{If}. This feature is essential because the leakage current \vec{If}, although small compared with the main currents \vec{IA} and \vec{IB}, generates a differential magnetic flux Ff in the magnetic circuit 5 which is predominant with respect to the magnetic fluxes FA and FB.

The main current measuring winding 11 forms a circuit in series with the voltage measuring means 13. The voltage measuring means 13 is typically a voltmeter and exhibits a high voltmeter internal resistance R13, for example greater than 1MΩ. Thus, the measurement of the main currents does not influence, or has a negligible influence on, the measurement of the differential current \vec{If}.

The voltage measuring means 13 thus measures the resulting voltage V11 at the terminals of the main current measuring winding 11. According to the above, the voltage measuring means 13 therefore measures a voltage dependent on the main currents \vec{IA} and \vec{IB} and independent of the leakage current \vec{If}.

The computing unit 15 receives the measurement of the current \vec{I7} supplied by the current measuring means 9 and the measurement of the voltage V11 supplied by the voltage measuring means 13, so as to deduce from these a value of differential current \vec{If} and values of the main currents \vec{IA} and \vec{IB}.

As previously explained, the value of the current \vec{I7} is proportional to the value of the leakage current \vec{If}. By virtue of a prior calibration step, the computing unit 15 therefore simply converts the measurement of the current \vec{I7} into a value of differential current \vec{If}. The computing unit 15 renders the value of differential current \vec{If} in an analog or digital form or uses it for controlling or otherwise the interruption of the power supply of the electrical installation.

As previously explained, the voltage V11 depends on the values of the main currents \vec{IA} and \vec{IB}. With the knowledge of the geometry of the device for measuring the main currents 1, and in particular the disposition of the conductors 3 fixed by the holding device 6, or else by virtue of a calibration step, the computing unit 15 converts the measurement of the voltage V11 into an equation on the main currents \vec{IA} and \vec{IB}. Since the leakage current \vec{If} is low compared with the values of the main currents \vec{IA} and \vec{IB}, for this measurement, the approximation may be made that the currents \vec{IA} and \vec{IB} are equal. This equality provides a second equation on the main currents \vec{IA} and \vec{IB}. As a variant not shown, the second equation on the main currents \vec{IA} and \vec{IB} may come from a similar reasoning on an additional main current measuring winding. Using these two equations on the main currents \vec{IA} and \vec{IB}, the computing unit 15 determines the values of each main current \vec{IA} and \vec{IB} and renders these values in an analog or digital form.

As a variant not shown, the device for measuring the main currents 1 comprises two separate computing units, one of the two computing units receiving the measurement of the current \vec{I7} and performing the conversion of the measurement of the current \vec{I7} and the other of the two computing units receiving the measurement of the voltage V11 and performing the conversion of the measurement of the voltage V11.

As a variant, the electrical installation is a split-phase electrical installation and the two conductors 3A and 3B are two phase wires.

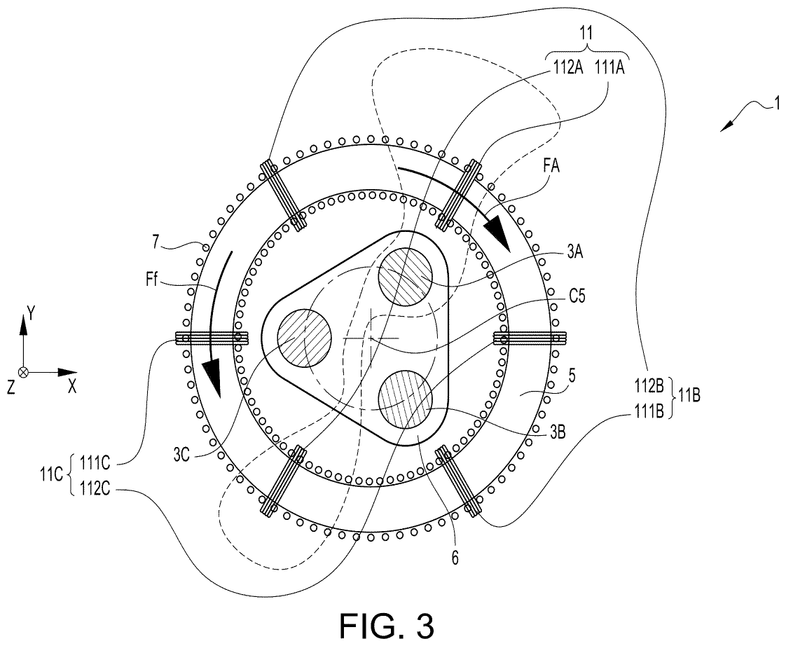

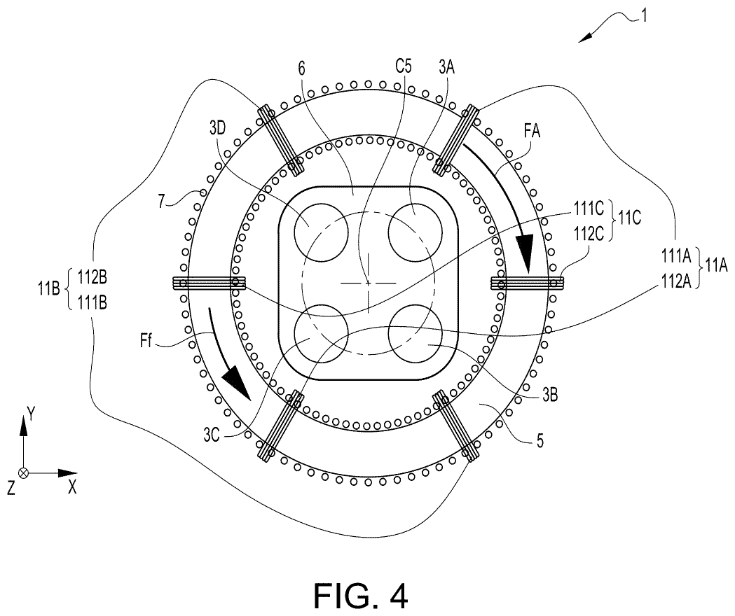

FIGS. 3 and 4 show a generalization of the example hereinabove in the case of an electrical installation respectively with three conductors and with four conductors. In the embodiments in FIGS. 3 and 4, the elements analogous to those of the first embodiment carry the same references. If a reference is mentioned in the following part of the description without appearing in one of the FIGS. 3 and 4 or appears in one of these figures without being mentioned in the following part of the description, it corresponds to the element carrying the same reference in the first embodiment. In the following, the differences between the example of the single-phase installation and the generalization to three conductors and to the four-pole system are principally described.

In the case of an installation with three conductors shown in FIG. 3, the main conductors are denoted 3A, 3B and 3C and the main currents flowing in these conductors 3A, 3B and 3C are respectively denoted \vec{IA}, \vec{IB} and \vec{IC}. The electrical installation is for example three-phase and the conductors 3A, 3B and 3C are then three phase wires. As a variant, two of the three conductors 3A and 3B are phase wires and the third conductor 3C is a neutral wire.

There are then at least two main current measuring windings 11. In FIG. 3, three main current measuring windings 11A, 11B and 11C are shown. As can be seen in FIG. 3, the two windings 111 and 112 of each main current measuring winding 11 are advantageously symmetrical to one another with respect to the center of symmetry C5 of the magnetic circuit 5, as in the embodiment in FIG. 2.

The two windings of the first main current measuring winding 11A are denoted 111A and 112A, the two windings of the second main current measuring winding 11B are denoted 111B and 112B and the two windings of the third main current measuring winding 11C are denoted 111C and 112C.

In this case, three equations with three unknowns \vec{IA}, \vec{IB} and \vec{IC} are obtained and solved by the computing unit 15, supplying the three values of main current \vec{IA}, \vec{IB} and \vec{IC}.

In the case of a four-pole installation, there are four conductors: three phase wires 3A, 3B and 3C and a neutral wire 3D, in which respective main currents \vec{IA}, \vec{IB}, \vec{IC} and \vec{ID} flow. In the example illustrated in FIG. 4, the device 1 is then similar to the case with three conductors and the fourth equation on the main currents comes from the approximation \vec{IA}+\vec{IB}+\vec{IC}=\vec{ID}.

The windings 111A, 112A, 111B, 112B, 111C and 112C of the main current measuring windings 11A, 11B and 11C are identified as in the embodiment in FIG. 3.

A voltage measuring means not shown, of the type of the voltage measuring means 13, is connected in series with each main current measuring winding 11A, 11B and 11C and allows a voltage of the type of the voltage V11 to be measured.

The implementation of a method for measuring the main currents of an electrical installation by means of a device for measuring the main currents 1 conforming to the above, after a potential calibration operation, is described in the following part of the description.

In operation, the main currents \vec{I} flowing in the N conductors 3 generate magnetic fluxes F in the magnetic circuit 5, which magnetic fluxes in turn generate a resulting current \vec{I7} in the differential current measuring winding 7 and voltages V11 and equivalents at the terminals of the main current measuring windings 11, 11A, 11B and 11C.

As previously explained, owing to the geometry of the device for measuring the main currents 1, the resulting current \vec{I7} in the differential current measuring winding 7 is proportional to the leakage current \vec{If} while being independent of the main currents \vec{I}.

Similarly, the resulting voltages V11 and equivalents at the terminals of the main current measuring windings 11, 11A, 11B and 11C are dependent on the main currents \vec{I} while being independent of the leakage current \vec{If}.

The method for measuring the main currents, implemented by the computing unit 15, then consists in:
receiving values of the voltage V11 at the terminals of each main current measuring winding 11, measured by the voltage measurement means 13;
deducing from these, by virtue of the knowledge of the geometry of the device for measuring the main currents 1 or of the prior calibration, the at least N−1 equations on the main currents \vec{I};
potentially, completing with an equation coming from the approximation of vector equality of the main currents of an electrical installation;
solving the system of N equations whose N unknowns are the N main currents \vec{I};
rendering the values of the main currents \vec{I} in analog or digital form.

Advantageously, the computing unit 15 implements in parallel the method for protecting the installation which consists in:
receiving a value I7 of the current \vec{I7} flowing in the differential current measuring winding 7, measured by the current measuring means 9;
deducing from this, by virtue of a coefficient of proportionality obtained by prior calibration, the value of the leakage current \vec{If};
controlling a switch allowing the power supply of the electrical installation to be interrupted if and only if the value of the leakage current \vec{If} is higher than a predetermined threshold value.

Thus, the main currents \vec{I} in the conductors 3 of the electrical installation are measured by means of the single device for measuring the main currents 1, while at the same time providing the protection function of a differential circuit breaker.

Any feature described hereinabove for an embodiment or a variant may also be implemented in the other embodiments or variants described hereinabove, with the proviso of being technically possible.

1. A device for measuring main currents of an electrical installation comprising a number N of conductors through which a main current \vec{I} flows, the device comprising:
a closed magnetic circuit, composed of a ferromagnetic material and set up to surround the conductors;
at least N−1 main current measuring windings, each main current measuring winding comprising two windings in series which:
i. are each wound around a part of the closed magnetic circuit,
ii. are not equidistant from at least one of the conductors, so that the main current \vec{I} flowing in said at least one conductor generates a different magnetic flux within each of the two windings, and
iii. have an opposite winding direction from one winding to the other, so that a uniform magnetic field in the magnetic circuit generates a voltage which cancels out at the terminals of the main current measuring winding;
a holding structure set up to hold the conductors in a given disposition where the conductors are non-coaxial;
means for measuring a voltage at the terminals of the N−1 main current measuring windings; and
a computing unit, connected to the means for measuring the voltage.

2. The device as claimed in claim 1, wherein the magnetic circuit has a symmetrical shape, in other words comprises at least one axis of symmetry and/or a center of symmetry.

3. The device as claimed in claim 2, wherein the at least one axis of symmetry is also an axis of symmetry of the holding structure.

4. The device as claimed in claim 2, wherein the two windings of each main current measuring winding are disposed symmetrically to each other with respect to the center of symmetry of the magnetic circuit or with respect to the at least one axis of symmetry.

5. The device as claimed in claim 4, wherein there are two main conductors, one of the conductors being a phase wire and the other being a neutral wire of a single-phase electrical installation or another phase wire of a split-phase electrical installation.

6. The device as claimed in claim 4, wherein there are three conductors, two of the three conductors being phase wires and the third conductor being a third phase wire or a neutral wire of an electrical installation.

7. The device as claimed in claim 4, wherein there are four conductors, three of the conductors being phase wires and the fourth being a neutral wire of an electrical installation.

8. The device as claimed in claim 1, comprising:
a differential current measuring winding, wound in a regular manner around the closed magnetic circuit, and
means for measuring a current flowing in the differential current measuring winding, connected to the computing unit or to another computing unit.

9. A method for measuring main currents of an electrical installation comprising a number N of conductors through which a main current \vec{I} flows, implemented by a computing unit of a device for measuring the main currents, the device comprising:
a closed magnetic circuit, composed of a ferromagnetic material and set up to surround the conductors;
at least N−1 main current measuring windings, each main current measuring winding comprising two windings in series which:
i. are each wound around a part of the closed magnetic circuit,
ii. are not equidistant from at least one of the conductors, so that the main current \vec{I} flowing in said at least one conductor generates a different magnetic flux within each of the two windings, and
iii. have an opposite winding direction from one winding to the other, so that a uniform magnetic field in the magnetic circuit generates a voltage which cancels out at the terminals of the main current measuring winding;
a holding structure set up to hold the conductors in a given disposition where the conductors are non-coaxial;
means for measuring a voltage at the terminals of the N−1 main current measuring windings; and
a computing unit, connected to the means for measuring the voltage;
the method comprising:
receiving values of the voltage at the terminals of each main current measuring winding, measured by the voltage measurement means;
converting the values of the voltage at the terminals of each main current measuring winding into values of the main currents, corresponding to the currents flowing in the main conductors; then
rendering the values of the main currents in analog or digital form.

10. A method for protecting an electrical installation comprising a number N of conductors through which a main current \vec{I} flows, the electrical installation having a leakage current defined as a difference between the sum of the main currents entering the electrical installation and the sum of main currents exiting the electrical installation, the method being implemented by a computing unit of a main current measuring device, the device comprising:
a differential current measuring winding, wound in a regular manner around a closed magnetic circuit surrounding the conductors, and
means for measuring a current flowing in the differential current measuring winding, connected to the computing unit;
the method comprising:
receiving a value of the current flowing in the differential current measuring winding, measured by the current measuring means;
deducing from this, by virtue of a coefficient of proportionality obtained by prior calibration, the value of the leakage current; then
controlling a switch allowing a power supply of the electrical installation to be interrupted if and only if the value of the leakage current is higher than a predetermined threshold value.

11. The device as claimed in claim 3, wherein the two windings of each main current measuring winding are disposed symmetrically to each other with respect to the center of symmetry of the magnetic circuit or with respect to the at least one axis of symmetry.

12. The device as claimed in claim 11, wherein there are two main conductors, one of the conductors being a phase wire and the other being a neutral wire of a single-phase electrical installation or another phase wire of a split-phase electrical installation.

13. The device as claimed in claim 11, wherein there are three conductors, two of the three conductors being phase wires and the third conductor being a third phase wire or a neutral wire of an electrical installation.

14. The device as claimed in claim 11, wherein there are four conductors, three of the conductors being phase wires and the fourth being a neutral wire of an electrical installation.

15. The method of claim 9, wherein the electrical installation has a leakage current defined as a difference between the sum of the main currents entering the electrical installation and the sum of the main currents exiting the electrical installation, and wherein the device comprises:
a differential current measuring winding, wound in a regular manner around the closed magnetic circuit, and
means for measuring a current flowing in the differential current measuring winding, connected to the computing unit;
the method further comprising:
receiving a value of the current flowing in the differential current measuring winding, measured by the current measuring means;
deducing from this, by virtue of a coefficient of proportionality obtained by prior calibration, the value of the leakage current; and
controlling a switch allowing a power supply of the electrical installation to be interrupted if and only if the value of the leakage current is higher than a predetermined threshold value.

16. The method of claim 10, wherein the device comprises:
at least N−1 main current measuring windings, each main current measuring winding comprising two windings in series which:
i. are each wound around a part of the closed magnetic circuit,
ii. are not equidistant from at least one of the conductors, so that the main current \vec{I} flowing in said at least one conductor generates a different magnetic flux within each of the two windings, and
iii. have an opposite winding direction from one winding to the other, so that a uniform magnetic field in the magnetic circuit generates a voltage which cancels out at the terminals of the main current measuring winding; and
means for measuring a voltage at the terminals of the N−1 main current measuring windings;
the method further comprising:
receiving values of the voltage at the terminals of each main current measuring winding, measured by the voltage measurement means;
converting the values of the voltage at the terminals of each main current measuring winding into values of the main currents, corresponding to the currents flowing in the main conductors; and
rendering the values of the main currents in analog or digital form.
